(19) United States
(12) Patent Application Publication
(10) Pub. No.: US 2010/0116531 A1
(43) Pub. Date: May 13, 2010

(54) Component with Mechanically Loadable Connecting Surface

(76) Inventors: Martin Maier, St. Wolfgang (DE); Michael Obesser, Bachenhausen (DE); Konrad Kastner, Grafing (DE); Juergen Portmann, Muenchen (DE); Ulrich Bauernschmitt, Grafing (DE)

Correspondence Address: SLATER & MATSIL, L.L.P., 17950 PRESTON RD, SUITE 1000, DALLAS, TX, 75252-5793, US

(21) Appl. No.: 12/620,027

(22) Filed: Nov. 17, 2009

Related U.S. Application Data
(63) Continuation of application No. PCT/EP2008/056200, filed on May 20, 2008.

(30) Foreign Application Priority Data
May 21, 2007 (DE) 10 2007 023 590.0

(51) Int. Cl. H05K 1/09; H05K 1/00; H05K 1/16; H05K 1/11

(52) U.S. Cl. 174/257; 174/250; 174/259; 174/256; 174/260; 174/261

(57) ABSTRACT

A component having a multilayer solderable or bondable connecting surface on a substrate is proposed, which, in addition to the electrically conductive pad metallization and the UBM metallization also has an electrically conductive stress compensation layer that is arranged between the substrate and the pad metallization or between the pad metallization and the UBM metallization. The insensitivity to stress of the connecting metallization is achieved by means of a stress compensation layer whose modulus of elasticity is less than that of the UBM metallization.

This application is a continuation of co-pending International Application No. PCT/EP2008/056200, filed May 20, 2008, which designated the United States and was not published in English, and which claims priority to German Application No. 10 2007 023 590.0 filed May 21, 2007.

BACKGROUND

Micro-electrical and micro-electromechanical components implemented in a chip, can, by means of a flip chip arrangement, be electrically connected through bumps to a carrier or to a circuit board. The carrier can establish the electrical connection between the chip and the circuit board. It can, in addition, constitute part of a cover for the protection of component structures arranged on the surface of the chip.

When a component is mounted with flip chip construction, stresses can occur as a result of mechanical action on the component itself, or, when the temperature changes, due to different coefficients of thermal expansion of the chip, carrier and/or circuit board, and these stresses can have an effect on the mechanical connection between the different materials, and, in particular, on the bump bonds between the chip and the carrier or circuit board. As a result the joint can be damaged or torn off, impairing the function of the component. A fault that occurs frequently here is that the bump together with the connecting pad tears away from the substrate.

An attempt is sometimes made to minimize the mechanical loading on the bump, and therefore the risk of fracture or tearing off, by using sufficiently large bumps with a diameter of, for instance, about 100 μm. With increasing component miniaturization, however, the size of bumps is being reduced, and this brings an increase in the components' susceptibility to stress.

### SUMMARY

Aspects of the present invention disclose a chip component with which thermal or mechanical stresses that arise can be minimized or compensated for.

The invention solves the problem through a special structure of the connecting metallization through which the component can be mounted by means of a bond or bump joint onto a carrier or circuit board and an electrical connection can be made. While a known connecting metallization comprises at least one pad metallization and a UBM (Under Bump Metallization), a stress compensation layer is proposed for the component, arranged either between the substrate and the pad metallization or between the pad metallization and the UBM metallization, and which has a lower modulus of elasticity than the UBM metallization.

The stress compensation layer makes it possible to reduce the forces acting on the connecting metallization in a component that is soldered or bonded by means of bumps, and to a large extent to absorb those forces in the stress compensation layer. The stress compensation layer can therefore more easily be deformed than the pad metallization and the UBM metallization, without the mechanical stability of the layer structure of the connecting metallization being lost.

Its material can be deformed plastically or elastically. Elastic deformation has the advantage that an initial deformation can, as a result of the elasticity, also be reversed, thus restoring the stress compensation function, i.e., of absorbing mechanical forces acting on the stress compensation layer. Since the stress compensation layer is electrically conductive, it can be arranged equally well under or over the pad metallization.

In one embodiment the stress compensation layer is comprised of metallic material arranged between the pad metallization and the UBM metallization, and structured together with the UBM metallization. The pad metallization is of a relatively large area, and, in this embodiment, is applied directly to the substrate of the component. It should be characterized by good adhesion of the connecting metallization to the substrate and adequate electrical conductivity to provide a low-resistance connection. The UBM metallization, which has a relatively small base area, determines the area that is available to establish an electrical and mechanical joint, for instance by means of a bump or a soldered joint. If the soldered joint is created through the UBM metallization, then the base area of the UBM metallization defines the diameter of the solder ball, which can wet the connecting metallization only there.

The stress compensation layer is thus a layer applied together with the UBM metallization; it does not contribute to the function of the UBM. It increases the thickness of the layer of connecting metallization, and thus constitutes an additional electrical resistor element. Correspondingly it results in a connecting metallization layer whose total thickness is significantly greater than the thickness of the layer of known connecting metallizations.

In one embodiment, the stress compensation layer is formed of or comprises a metal that is more ductile than the metal of the pad metallization. It is also possible to obtain a lower ductility for the stress compensation layer if it is made of a metal that is chemically identical to that of the pad metallization. Thus, for instance, an aluminum layer deposited on a different surface first grows with stress, and only develops a structure that is free from tension, and is therefore more ductile, as the thickness of the layer grows beyond a certain value that depends on the growth conditions. When this range of thicknesses is reached, the layer is then more ductile than a relatively thin layer of the same metal.

It is, however, also possible to build the stress compensation layer of a number of constituent layers. A first adhesive layer comprising titanium or chromium, can thus be arranged between the stress compensation layer and the UBM metallization or between the pad metallization and the UBM metallization. As a result, the UBM metallization at a solder or bonding point will not be torn off the pad metallization even under the influence of tensile or shearing forces. When a stress compensation layer is arranged between the pad metallization and the UBM metallization, the first adhesive layer can be formed as the topmost layer of the pad metallization as well as the topmost layer of the stress compensation layer. It is, moreover, advantageous to provide a further adhesive layer immediately before applying the UBM, and for this to be structured together with the UBM metallization.

The connecting metallization can be given further, improved resistance to stress if the lower layer region of the connecting metallization, which, depending on the structure of the sequence of layers, may consist of the pad metallization or the stress compensation layer, is structured at least in the region of the UBM metallization. The structuring is, for example, carried out in such a way that the lower layer region is removed from certain partial areas, so that in those places the substrate is in direct contact with the upper layer region of the connecting metallization that lies immediately above it.

For this purpose, at least one depression in the form of a blind hole is formed in the lower layer region, permitting the lower and upper layer regions to interlock. It is advantageous for the lower and upper layer regions to have multiple interlocks. This can be done through a formation that has alternating, in particular, regular patterns taking, for instance, the form of multiple parallel stripes. However, checkerboard-like structuring, for example, or a pattern of depressions extending over the structured region of the surface, are also possible. The interlocking of the lower and upper layer regions increases the surface area of the boundary layer, and this alone provides improved adhesion between the lower and upper layer regions and, in particular, between the constituent layers of the connecting metallization that form the two layer regions.

When the lower layer region is structured, and correspondingly interlocked with the upper layer region, the first adhesive layer can, in addition, be provided between these two layer regions. A further adhesive layer can be provided between the substrate and the pad metallization.

The stress compensation layer is advantageously selected from a metal that is heavier than the metal of the pad metallization and that is adequately electrically conductive. The metal of the stress compensation layer can, moreover, be selected in such a way that it can form a bond with low electrical resistance and good adhesion to the neighboring layer regions of the connecting metallization. The stress compensation layer comprises, for example, a metal selected from copper, molybdenum or tungsten.

Immediately below the UBM metallization, or comprising the lowest constituent layer of the UBM metallization, a diffusion barrier layer can be provided, formed, for instance, of platinum, nickel, tungsten or palladium. As a further layer, the UBM metallization can comprise a bondable, and therefore not too strongly passivated, metal layer that can alloy with the solder. A layer of gold is therefore particularly suitable as the top layer of the UBM metallization. It is also possible to implement the top layer as a layer of copper, coated, for example, with an OSP (organic surface passivation) layer that is burnt away or melted under the process conditions used to create the bond joint. It is also possible to use a layer of pure copper as the top layer of the UBM, whose surface can then be activated immediately before making the bond joint, for instance, by means of an etching step to remove oxide layers that have formed.

The UBM metallization can, moreover, comprise a double nickel/copper layer.

All of the constituent layers of the connecting metallization can be applied using known thick-layer or thin-layer methods. It is nevertheless advantageous to sputter at least the lowest layer, for instance, a thin layer comprising titanium, onto the substrate, which normally is not electrically conductive. A layer of this sort can be reinforced by further thin-layer processes. It is, however, also possible to reinforce what is now an electrically conductive layer by electroplating or by means of a currentless method. A multi-layer structure can also be manufactured in this way through the use of different galvanic baths.

There can be active, electrically conductive component structures, in the form of structured, active metallization, on the surface of the substrate. The component structures and the connecting metallization can be connected together by an additional metallization that is different from the active metallization. It is nevertheless advantageous if the pad metallization is structured in such a way that it contacts the component structures directly.

In a different version of a stress-compatible component, as an alternative to the embodiments proposed further above, a dielectric stress compensation layer is proposed, arranged between the substrate and the connecting surface, and having a lower modulus of elasticity than the connecting metallization.

Means are provided to make a connection that is electrically conductive and that has guaranteed tensile strength between the component structures that are arranged on the substrate and the connecting metallization. This connection can be implemented as a self-supporting spring element with a clearance from the surface of the substrate and/or as a constituent layer of the connecting metallization; in the latter case the constituent layer sits on the substrate and reaches over the structured stress compensation layer like a bridge. A bridge-shaped constituent layer of the connecting metallization of this sort can be implemented as a strip that passes over a structured stress compensation layer and sits on the substrate at both ends. It is, nevertheless, also possible to implement the lowest constituent layer of the connecting metallization in such a way that it overlaps the structured stress compensation layer on all sides. The latter layer is thus fully enclosed between the substrate and the constituent layer.

This has the advantage that the connecting metallization can adhere directly and firmly to the substrate, independently of the material selected for the stress compensation layer.

The stress compensation layer is structured in such a way that it is arranged, at least in the region of the UBM metallization, directly beneath the area provided for making a bonded joint. Because this area is small in comparison with the total area of the pad metallization, the base area of the structured stress compensation layer can also be small in comparison with the area of the pad metallization. The material of a fully embedded stress compensation layer consisting, for instance, of an organic plastic, can therefore be selected from a large number of materials, and, in particular, from soft materials with very low moduluses of elasticity, without the need to place high demands on the mechanical strength or on good adhesion to neighboring surfaces.

In the second alternative embodiment, the connecting metallization can be arranged entirely on the stress compensation layer, without overlapping it or being in contact with the substrate. The stress compensation layer is then favorably thinner than it is in the other embodiments. The electrical connection to the component structures is made through a spring element that is capable of compensating for tensile or compressive forces resulting from deformations or expansions. These can, in particular, develop as a result of shear forces acting on the component, such as can, for instance, arise as a consequence of thermal stresses when the material of the substrate and carrier or of the substrate and the circuit board are different.

The spring element can be constructed as a separate element and can, for instance, be a bond wire. Nevertheless it is advantageous for the spring element to be formed as a structured constituent layer of the connecting metallization.

A self-supporting spring element arranged with a clearance from the surface of the substrate can be manufactured with the aid of an auxiliary or sacrificial layer onto which the metal layer to be used for the spring element is applied. Either immediately at the time of application or subsequently, the spring element is processed to form a structure that is not a straight line and that favorably incorporates one or more bent or angled sections. The auxiliary layer can then be removed, as a result of which the structured spring element remains as a self-supporting element.

A contact metallization lying directly on a stress compensation layer and, in particular, not in contact with the substrate, also comprises a pad metallization with a UBM metallization on top.

### BRIEF DESCRIPTION OF THE DRAWINGS

The invention is described below in more detail with the aid of exemplary embodiments and of the associated illustrations. These only have the purpose of illustrating the invention, and are therefore only shown schematically, and not true to scale. Neither absolute nor relative dimensions can therefore be taken from the figures.

FIG. 1, including FIGS. 1a and 1b, shows a cross-section of first and second exemplary embodiments;

FIG. 2 shows a top view of these embodiments;

FIG. 3, including FIGS. 3a and 3b, shows a cross-section and a top view of a third exemplary embodiment;

FIG. 4 shows a cross-section of a fourth exemplary embodiment;

FIG. 5 shows a cross-section of a possible sequence of layers for a connecting metallization; and

FIG. 6 shows a cross-section of a fifth exemplary embodiment.

The following list of reference symbols may be used in conjunction with the drawings:

SU Substrate

PM Pad metallization

SK Stress compensation layer

UBM UBM metallization

ZL Lead

FE Spring element

HR Free space

BES Component structures

HS Adhesive layer

### DETAILED DESCRIPTION OF ILLUSTRATIVE EMBODIMENTS

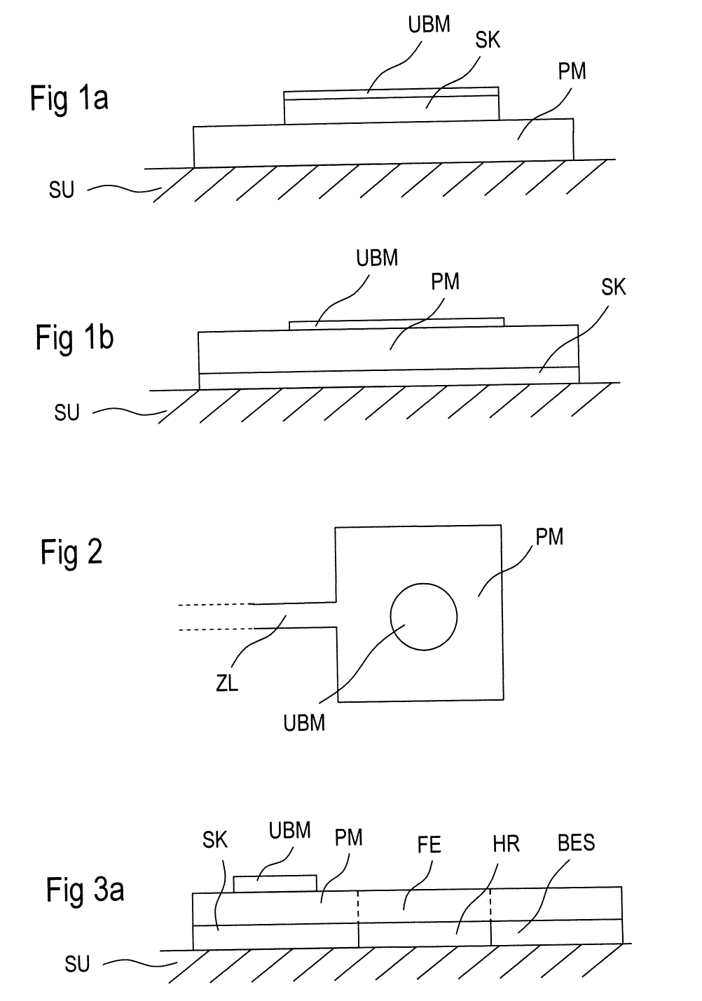

FIG. 1a shows a schematic cross-section of a simple embodiment of the invention. A pad metallization PM is applied in a conventional manner and thickness onto a substrate SU. The pad metallization PM is made from a material with good electrical conductivity, consisting, for instance, of aluminum or of an aluminum alloy. It is also possible for the pad metallization PM and the electrical component structures not shown in the illustration to use the same structure.

The pad metallization PM is electrically connected to the component structures, and has a relatively large area for adequate adhesion to the substrate. An electrically conductive stress compensation layer SK is arranged immediately above the pad metallization PM. It is favorably arranged centrally on the pad metallization PM, and has a smaller base area than the pad metallization PM.

The stress compensation layer SK comprises a material whose modulus of elasticity is lower than the under bump metallization UBM arranged immediately above it. The UBM metallization and the stress compensation layer SK are favorably structured in the same structuring process step. This can, for instance, be done by applying and structuring, over the pad metallization PM, a metallization mask with spaces over the areas required for depositing the stress compensation layer SK and the UBM metallization. This makes it possible to deposit the stress compensation layer SK and the UBM metallization of the required thickness directly onto the pad metallization PM from the solution by means of a currentless or galvanic method.

Suitable materials for the stress compensation layer SK include, in particular, sufficiently thick layers of aluminum, having a thickness of, for example, 100 to 1500 nm. The stress compensation is only achieved with an aluminum layer that is this thick since an aluminum layer grown on any metallic base forms first with stresses in the lowest layer region, perhaps 50 nm thick, which therefore has a relatively high modulus of elasticity. Layers that grow beyond this thickness can form with greater relaxation, and therefore have a lower modulus of elasticity than the stressed part of the aluminum layer at the bottom.

It is also however possible for the stress compensation layer SK to comprise a material that has an inherently lower modulus of elasticity than the UBM metallization. Molybdenum, tungsten or copper may particularly be considered here.

The UBM metallization is applied over the stress compensation layer SK to a total thickness of about 1 or 2 μm. It can comprise a number of constituent layers. The lowest constituent layer can, for instance, be an adhesive layer. The metals titanium and chromium are particularly suited for this purpose. The adhesive layer can have a thickness of between 10 and 100 nm.

Another constituent layer is a diffusion barrier layer, manufactured, for instance, from nickel or from a nickel alloy. A thickness of, for instance, between 100 nm and 1000 nm is suitable for this purpose. As further constituent layers on top of this, metal layers may be applied that adhere well to the solder metal or to the bond joint and that, for instance, can form an alloy with solder, favorably however being a layer of copper with a thickness of about 500 to 1500 nm. A layer of gold may be in addition be provided as the topmost constituent layer, ensuring passivation of the UBM and therefore easier solderability. This layer can be applied with a thickness of 50 to 500 nm.

FIG. 1b shows a further embodiment of a connecting metallization, improved with respect to the stresses acting on the UBM. In this case the sequence of the stress compensation layer SK and the pad metallization PM is reversed, so that the stress compensation layer SK is arranged between the substrate and the pad metallization PM. The stress compensation layer SK is accordingly relatively large, and its form is adapted to the area of the pad metallization PM.

The base area of the UBM metallization is restricted to the size of the later bonding and soldering joint, and is significantly smaller than the base area of the pad metallization PM. A further adhesive layer can be provided between the substrate SU and the stress compensation layer SK, which here again is manufactured from an electrically conductive material. A further adhesive layer can constitute the bottom layer of the UBM metallization.

FIG. 2 shows a top view of a possible structuring of the pad metallization PM and of the UBM metallization UBM. The pad metallization PM is relatively large in area in order to provide, on the one hand, an adequate base area for fabricating the bond or solder joint. On the other hand, the area is chosen to be sufficiently large that the force necessary to tear off the whole solder or bonding site is high enough.

The pad metallization PM is connected via a lead ZL, which can be made from the same material as the pad metallization PM or from a different material, such as that of the component structures (not shown in the illustration).

The UBM metallization UBM determines the size of the solder or bond connection, and is preferably arranged centrally on the pad metallization PM. The good adhesion between even different metal layers also means that the UBM adheres sufficiently well to the pad metallization PM that is underneath. The stress compensation layer SK, not shown in FIG. 2, can be structured in the same way as in FIG. 1a between the pad metallization PM and the UBM metallization, and, as in FIG. 1, together with the UBM metallization. It is however also possible for the stress compensation layer SK to be structured together with the pad metallization PM and to be arranged between the pad metallization PM and the substrate SU.

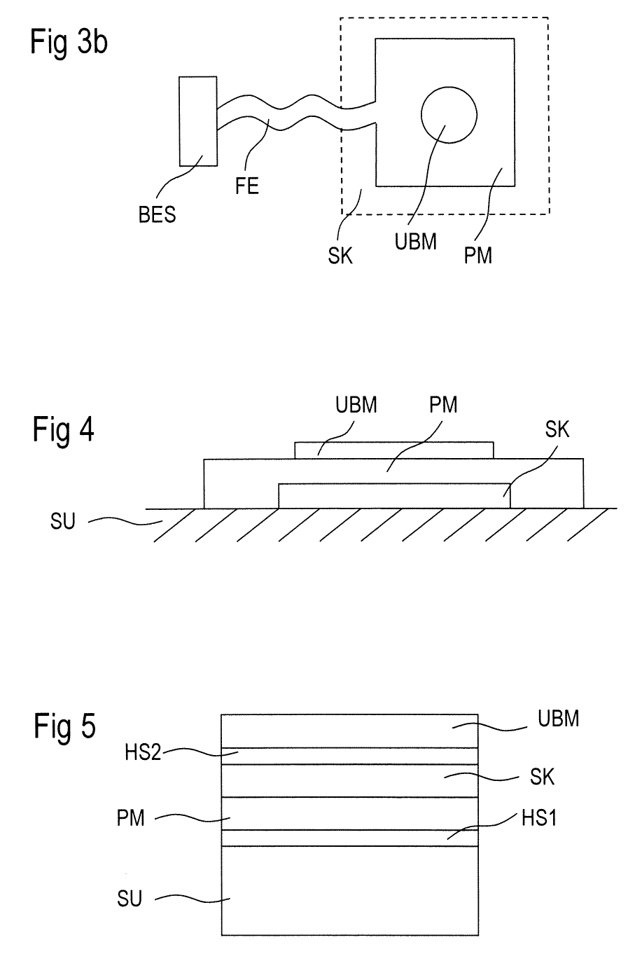

FIG. 3a shows a further embodiment of the invention in which not only the combination of the bond joint and the connecting metallization, but also the electrical connection between the pad metallization PM and the component structures BES, have a greater capacity to withstand stress. This is achieved by constructing the electrical connection between the component structures BES and the pad metallization PM in the form of a spring element FE, positioned with a gap from the surface of the substrate SU and which, in particular, has a reserve capacity for expansion. The lead and the pad metallization PM can be structured from the same layer, whereby the free space underneath the spring element FE can be created through the use of a sacrificial layer that is later etched or dissolved to remove it. There is a free space HR between the spring element FE and the substrate SU.

FIG. 3b shows a top view of such an electrical connection, implemented as a spring element FE, between the pad metallization PM and the component structures BES, which are only illustrated schematically. The spring element FE does not extend in a straight line, but may have a number of bends or angles. A stress compensation layer SK is provided between the pad metallization PM and the substrate SU, and can have the same base area as the pad metallization PM. Favorably, and as suggested by the dotted line in FIG. 3b, the stress compensation layer SK may nevertheless also have a larger base area.

The advantage of this embodiment is that a force that might act in any direction on the lead or the spring element FE can be compensated for by a reserve capacity for expansion or deformation of the spring element, without this resulting in the electrical connection or the spring element being torn off. In comparison with a straight lead ZL as shown in FIG. 2, it is possible in this way to compensate for both shearing forces that act in parallel with the surface of the substrate and for tensile or compressive forces acting normally to the surface, so ensuring increased durability of the connecting metallization and therefore of the component. In this embodiment, the stress compensation layer SK can also be a dielectric layer, since the sequence of layers and the electrical contact made through the spring element FE mean that electrical conductivity is not required. Layers consisting of organic polymer or plastic, which can be implemented with a particularly low modulus of elasticity, are therefore preferred. A pad metallization PM, complete with UBM, applied on top of this is therefore particularly resistant to any force that might act on it either normally or transverse to the surface of the substrate.

FIG. 4 illustrates a further embodiment of a stress compensated connecting metallization, in which a stress compensation layer SK is arranged directly on the substrate SU. The pad metallization PM that is applied on top overlaps the stress compensation layer SK on at least on two sides. Preferably the stress compensation layer SK is fully enclosed between the pad metallization PM and the substrate SU, whereby the pad metallization PM overlaps the stress compensation layer SK on all sides, and therefore encloses the substrate SU on all sides. In this embodiment again, few demands are made on the material of the stress compensation layer SK, as on the one hand it is protected against environmental influences, and on the other hand it can also withstand without damage structuring and processing steps that comprise treatment with solvents or aggressive media. Accordingly, the stress compensation layer SK in this exemplary embodiment can again consist of an organic polymer. A UBM metallization is again provided over the pad metallization PM, favorably in the region of the base area, and covered by the stress compensation layer SK. Such an implementation again can cushion compressive forces that act on the UBM particularly well, without this resulting in unacceptably high mechanical stresses being applied to the overall layer construction.

FIG. 5 shows a cross-section of a possible layer structure for the total connecting metallization. A first adhesive layer HS1 can be arranged between the substrate SU and the pad metallization PM. Another adhesive layer HS2 can be arranged between the stress compensation layer SK and the UBM metallization UBM. As has already been explained, the UBM also can comprise multiple constituent layers.

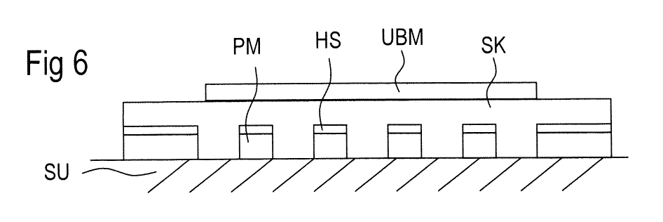

FIG. 6 shows a further option for improving the adhesion of the connecting metallization and increasing its capacity to withstand mechanical loading by means of a stress compensation layer SK. In this embodiment, the pad metallization PM is structured, so that structural elements of the pad metallization PM alternate with exposed surfaces of the substrate SU between them. The structuring can, for instance, take the form of stripes.

An optionally applied adhesive layer HS is structured together with the pad metallization PM. A stress compensation layer SK is now applied over the whole area, and accordingly comes into contact with the surface of the substrate SU between the structural elements of the pad metallization PM. The stress compensation layer SK is made of an electrically conductive material with a lower modulus of elasticity than the UBM, and preferably a lower modulus of elasticity than either the UBM or the pad metallization PM.

The surface of the stress compensation layer is planarized. This can be achieved through an application method that has a planarizing effect. It is also, however, possible to obtain a planar surface on the stress compensation layer SK through subsequent procedures such as chemical/mechanical polishing (CMP). The UBM metallization is arranged on the stress compensation layer SK, preferably in its structured region. The structuring provides a particularly intimate bond between the layers of the pad metallization PM, the stress compensation layer SK and the UBM, permitting increased resistance to being torn off and, in addition, increased capacity of the entire connecting metallization to compensate for stresses.

Connecting metallizations that are implemented as proposed, increase the capacity to withstand stress of the connecting metallization on very different substrates for very different components.

Preferably the invention is employed to construct connecting metallizations for components assembled using flip chip technology having delicate component structures, and that are subsequently covered with encapsulating plastic material, for instance by dripping or, advantageously, by overmolding with a polymer. When overmolding, in particular, the molding process subjects the components to pressures greater than 50 bar. Components bonded as flip chips, in particular, are thereby subjected to loading of the bond connections, including the connecting metallization, between the chip on the carrier or between a chip and the circuit board. Components bonded as flip chips with no underfill at the edges between the carrier and the chip, so that all the pressure exerted on the component acts directly on the bond joint, are particularly favorable. The invention is particularly suitable for MEMS (Micro Electro-mechanical System) components such as sensors or acoustic components, in particular, components that operate using acoustic volume waves (BAW components) or with acoustic surface waves (SAW components).

The invention is not restricted to the exemplary embodiments illustrated in the figures, and is defined solely through the patent claims. Variations, in particular with respect to the structuring, the thickness of the layers or the materials used, are possible. A connecting metallization according to the invention can also include additional constituent layers that cannot be described here in detail due to the large number of possibilities. These additional constituent layers can contribute to the electrical conductivity, to improvement of the soldering and bonding capacity, or to improvement of the adhesion between different constituent layers or between the connecting metallization and the substrate. Further constituent layers may serve to passivate the surface, i.e., to protect the UBM from oxidation.

What is claimed is:

1. A component comprising:
a substrate having a multi-layer solderable or bondable connecting surface;
a pad metallization arranged over the substrate to provide sufficient electrical conductivity for electrical connection;
a solderable or bondable UBM metallization arranged over the pad metallization, the UBM metallization having a smaller base area than the pad metallization; and
an electrically conductive stress compensation layer arranged between the substrate and the pad metallization, or between the pad metallization and the UBM metallization, the stress compensation layer having a lower modulus of elasticity than the UBM metallization.

2. The component according to claim 1, wherein the stress compensation layer comprises a metallic material, wherein the stress compensation layer is arranged between the pad metallization and the UBM metallization, and wherein the pad metallization and the stress compensation layer have the same base area.

3. The component according to claim 1, wherein the stress compensation layer comprises a metal that is more ductile than the pad metallization.

4. The component according to claim 1, wherein the stress compensation layer comprises a plurality of constituent layers.

5. The component according to claim 1, further comprising a first adhesive layer comprising titanium or chromium arranged between the stress compensation layer and the UBM metallization or between the pad metallization and the UBM metallization.

6. The component according to claim 5, wherein the first adhesive layer forms a topmost layer of the pad metallization or of the stress compensation layer.

7. The component according to claim 6, further comprising a second adhesive layer arranged directly underneath the UBM metallization, the second adhesive layer and the UBM metallization being structured together.

8. The component according to claim 1, wherein at least a lower layer region of the multi-layer connecting surface, comprising the pad metallization and/or the stress compensation layer in a region of the base area of the UBM metallization, is structured and comprises partial areas in which the lower layer region is removed and the substrate is in direct contact with an upper layer region.

9. The component according to claim 8, wherein the lower layer region has multiple interlocks with the upper layer region.

10. The component according to claim 8, further comprising a first adhesive layer between the structured lower layer region and the upper layer region.

11. The component according to claim 1, further comprising an adhesive layer between the substrate and the pad metallization or between the substrate and the stress compensation layer.

12. The component according to claim 1, wherein the pad metallization comprises a layer of aluminum or of an alloy that contains aluminum, wherein the stress compensation layer is arranged over the pad metallization and also comprises a layer of aluminum or of an alloy that contains aluminum, wherein the stress compensation layer has a thickness such that stresses associated with operation of the component are relaxed within the stress compensation layer.

13. The component according to claim 1, wherein the stress compensation layer comprises a metal that is heavier than a primary material of the pad metallization.

14. The component according to claim 13, wherein the stress compensation layer comprises copper, molybdenum or tungsten.

15. The component according to claim 1, further comprising a diffusion barrier layer comprising platinum, nickel, tungsten or palladium immediately beneath the UBM metallization.

16. The component according to claim 1, wherein the UBM metallization comprises a layer of gold, a layer of copper, or a layer of copper with an organic passivation layer as its topmost layer.

17. The component according to claim 1, wherein the UBM metallization comprises a double layer of nickel/copper.

18. The component according to claim 1, further comprising:
active component structures applied to a surface of the substrate that comprise an active metallization; and
leads that make an electrically conductive connection between the component structures and a connecting surface, and the leads consisting of a different material and/or having a different layer structure than the pad metallization.

19. A component comprising:
a substrate;
electrically conductive component structures arranged on the substrate;
at least one electrically connecting metallization having an electrically conductive connection to the component structures;
a structured, dielectric stress compensation layer arranged between the substrate and a connecting surface, the stress compensation layer having a lower modulus of elasticity than that of the connecting metallization,
a connection from the connecting metallization to the component structures, the connection having tensile strength, wherein the connection comprises a self-supporting spring element and/or as a constituent layer of the connecting metallization that sits on the substrate and extends bridge-like over the stress compensation layer.

20. The component according to claim 19, wherein the stress compensation layer is overlapped on all sides by a constituent layer of the connecting metallization, and is therefore fully enclosed between the constituent layer and the substrate.

21. The component according to claim 19, wherein the connection comprises a self-supporting spring element, wherein the spring element comprises a lead that has curves and/or angles.

22. The component according to claim 19, wherein the connection comprises a self-supporting spring element, wherein the spring element is formed from a structured constituent layer of the connecting metallization.

23. The component according to claim 19, wherein the stress compensation layer comprises a plastic material.

24. The component according to claim 19, wherein the connecting metallization comprises:
a pad metallization lying directly on the stress compensation layer; and
a UBM metallization over the pad metallization.
